(19) United States
(12) Patent Application Publication
(10) Pub. No.: US 2024/0235083 A9
(43) Pub. Date: Jul. 11, 2024

(54) CONTACT ASSEMBLY FOR AN ELECTRICAL PLUG CONNECTOR WITH A HEAT CAPACITY ELEMENT ARRANGED ON A LOAD LINE

(71) Applicant: PHOENIX CONTACT E-Mobility GmbH, Schieder-Schwalenberg (DE)

(72) Inventor: Thomas Fuehrer, Blomberg (DE)

(21) Appl. No.: 18/484,468

(22) Filed: Oct. 11, 2023

(30) Foreign Application Priority Data
Oct. 24, 2022 (BE) BE2022/5857

(51) Int. Cl. H01R 13/04; B60L 53/16; H01R 13/533

(52) U.S. Cl. CPC H01R 13/04; B60L 53/16; H01R 13/533; H01R 2201/26

(57) ABSTRACT

A contact assembly for an electrical plug connector includes: at least one contact element with a first end region for connecting to a corresponding plug connector, and a second end region facing away from the first end region; a load line, an end section of an insulating-sleeve-free region of the load line being connectable to the second end region of the at least one contact element; and a heat capacity element arrangeable at least in regions on the insulating-sleeve-free region of the load line.

### CROSS-REFERENCE TO PRIOR APPLICATION

Priority is claimed to Belgian Patent Application No. BE 2022/5857, filed on Oct. 24, 2022, the entire disclosure of which is hereby incorporated by reference herein.

### FIELD

The invention relates to a contact assembly for an electrical plug connector and to an electrical plug connector, in particular to a charging connector of a charger for charging an electric vehicle.

### BACKGROUND

Such a contact assembly for an electrical plug connector has at least one contact element with a first end region, which is designed to connect to a corresponding plug connector, and a second end region facing away from the first end region. The contact assembly has a load line, wherein an end section of an insulating-sleeve-free region of the load line can be connected to the second end region of the at least one contact element.

Especially in the field of e-mobility, there are high demands on the ampacity and the associated thermal loads of plug connectors and associated cable assemblies. The plug connectors, like the cables, are regularly exposed to high charging currents, for example of 800 ampere and more. These high currents are to be transmitted with the lowest possible power loss. The power loss increases with the square of the current.

For rapid charging with direct current, the charging times are often between 10 and 30 minutes, wherein these charging times are to be reduced further in the future. Due to the large masses of the current-conducting parts, the heating curves are pronounced to such an extent that the equilibrium temperature is sometimes reached only after several minutes even at higher currents. The established standard here is that no component within the plug connection may experience a temperature increase of more than 50 kelvin at any time during charging. Due to the normative definition of plug connectors in the field of e-mobility, it is not possible to scale the geometries of the contact elements to thus realize a greater ampacity and a lower temperature increase. Rather, the largest possible power transmission is to be achieved with the existing standardized plug connector geometries and, at the same time, the resulting current heat in the plug connector is to be made controllable.

This has often been successfully achieved with actively cooled plug connectors and charging cables. However, the technical effort usually required for this is reflected in the costs and effort to produce the actively cooled components of the corresponding chargers. DE 10 2016 107 409 A1 proposes, for example, a plug connector with active cooling.

Documents DE 10 2016 105 308 A1 and U.S. Pat. No. 10,535,940 B2 describe contact assemblies with contact elements on which heat capacity elements are arranged. As is customary in the prior art, these heat capacity elements are both thermally and electrically conductively connected to the contact elements.

The heat capacity elements are often formed from materials which are both thermally and electrically conductive. Metals or graphite-based materials are often used for this purpose.

However, connection of the heat capacity elements known from the prior art to the contact elements is often complex, since the contact elements often have to have specific geometries for connecting the heat capacity elements. The available installation space in the electrical plug connectors is also often limited.

### SUMMARY

In an embodiment, the present invention provides a contact assembly for an electrical plug connector, comprising: at least one contact element with a first end region configured to connect to a corresponding plug connector, and a second end region facing away from the first end region; a load line, an end section of an insulating-sleeve-free region of the load line being connectable to the second end region of the at least one contact element; and a heat capacity element arrangeable at least in regions on the insulating-sleeve-free region of the load line.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIGS. 1A-1D show schematic views of a contact assembly according to a first embodiment;

FIGS. 2A-2D show schematic views of a contact assembly according to a second embodiment; and

FIGS. 3A-3C show schematic views of an electrical plug connector according to embodiments of the invention.

### DETAILED DESCRIPTION

In an embodiment, the present invention provides a contact assembly with a heat capacity element, which can dissipate heat generated by a current flow through the contact element and which can be used with a plurality of differently configured contact elements, and which at the same time enables a simple and space-saving configuration.

Accordingly, the contact assembly for an electrical plug connector has at least one contact element with a first end region, which is designed to connect to a corresponding plug connector, and a second end region facing away from the first end region. The contact assembly also has a load line, wherein an end section of an insulating-sleeve-free region of the load line can be connected to the second end region of the at least one contact element. Furthermore, the contact assembly has a heat capacity element which can be arranged at least in regions on the insulating-sleeve-free region of the load line.

The at least one contact element can be formed in one piece or in multiple parts from a conductive material and can have a cylindrical cross section at least in regions. The first end region can be designed as a contact pin or as a contact socket for connecting to a corresponding contact socket or a corresponding contact pin of a corresponding plug connector. The second end region can have a receiver in order to connect the electrical line designed as a load line. For example, the contact element can be configured to transmit electrical currents of greater than 300 A, for example of up to 800 A.

The load line can be referred to herein also as load cable or only as cable and can have a conductor made of an electrically conductive material, such as copper. The conductor can be formed as a solid conductor from a firm string, or as a stranded conductor made of several stranded wires, which can also be referred to as leads and are combined in a composite. The conductor cross section can be cylindrical, square, rectangular or flat at least in regions.

The conductor can have an insulating sleeve made of a plastic material, such as, for example, PE (polyethylene), PP (polypropylene), PVC (polyvinyl chloride), PUR (polyurethane), etc.

The insulating-sleeve-free region of the load line can be a region of the conductor on which no insulating sleeve is arranged at least in regions, or where the insulating sleeve has been removed completely or in regions. An end section of the insulating-sleeve-free region is connectable to the second end region of the contact element to produce an electrical connection. The end section of the insulating-sleeve-free region can also be an end section or an end of the conductor.

The heat capacity element can be formed in a block shape and in one piece from a metal or a graphite-based material. The heat capacity element can comprise or be formed from a phase-change material. The heat capacity element can be formed from a single material or also from a plurality of different materials. The heat capacity element is configured to receive heat from the contact element. The heat capacity element is thermally connected to the contact element via the load line, so that heat can flow from the contact element into the heat capacity element and be absorbed there. This is based on the idea of providing an increased heat capacity on an electrical plug connector, as a result of which heating of the electrical plug connector, in particular of the contact element of the electrical plug connector, can be at least slowed down. This may make sense, for example, in an electrical plug connector for a charger for charging an electric vehicle and can effectively prevent excessive heating on such a charger.

To arrange the heat capacity element on the insulating-sleeve-free region of the load line, the heat capacity element can have a connecting surface which is designed to substantially correspond to a connecting surface of the load line, such as, for example, a conductor geometry of the load line. The heat capacity element can be held on the load line, for example, by means of a holding element such as a resilient tensioning element or a clamping part. For example, the thermal capacity element can be held on the load line at a distance from the end of the conductor so that the heat capacity element does not touch the contact element when the end section of the insulating-sleeve-free region of the load line is connected to the second end region of the at least one contact element. Such an arrangement in which the heat capacity element does not touch the contact element may also be referred to as a spaced arrangement of the heat capacity element relative to the contact element. For example, in a mounted position of the contact assembly, the distance between the second end region of the contact element and a side of the heat capacity element facing the contact element can be a few millimeters to a few centimeters, for example in a range from 1 mm to 2 cm.

In the mounted position, the end section of the insulating-sleeve-free region of the load line is connected to the second end region of the at least one contact element, and the heat capacity element is arranged at least in regions on the insulating-sleeve-free region of the load line.

By arranging the heat capacity element on the load line, heat can efficiently be dissipated from the contact element without the heat capacity element being directly connected to the contact element.

In one embodiment, the insulating-sleeve-free region of the load line has a first connecting surface, and the heat capacity element has a second connecting surface corresponding to the first connecting surface.

A stable connection between the load line and the heat capacity element can be created by connecting surfaces which are designed to correspond to one another.

In one embodiment, the first connecting surface and the second connecting surface are designed to be flat or curved.

In one embodiment, the first connecting surface and the second connecting surface are cylindrical, wherein the insulating-sleeve-free region of the load line lies at least in regions in an opening of the heat capacity element.

In one embodiment, the contact assembly comprises an insulating material which can be arranged between the first connecting surface and the second connecting surface for electrically insulating the heat capacity element with respect to the load line.

The insulating material is designed to be electrically insulating, but thermally conductive. For this purpose, the insulating material preferably has a sufficiently high electrical resistance and a sufficiently low thermal resistance. By arranging the heat capacity element by means of an insulating material on the load line, heat produced can be dissipated well, with reliable, strong electrical insulation of the heat capacity element from the load line.

For example, the insulating material can be designed as a film, in particular as a polyimide film, wherein the film has a material thickness in a range of 0.01 mm to 0.1 mm, in particular in a range of 0.02 mm to 0.08 mm. For example, the insulating material can have a thermal conductivity in a range of 0.1 W/(mK) to 0.3 W/(mK), in particular 0.2 W/(mK). The film can also have at least one adhesive layer, wherein the adhesive layer is arranged on at least one side of the film, in particular over the entire surface. The film can also be tubular and extend at least in regions around the heat capacity element.

The insulating material can also be formed in layers with a thermal conductivity of up to 5 W/(mK), and can, in particular, comprise a silicone rubber material. Furthermore, the insulating material can be formed as an injection-molded part made of a thermally conductive thermoplastic material or as a coating, in particular as a paint or powder coating.

In one embodiment, the contact assembly comprises a holding element for holding the heat capacity element on the load line.

For example, in a mounted position the holding element can extend as a belt around the load line and the heat capacity element. The holding element can be manufactured, for example, from an elastically resilient material and can clamp the heat capacity element to the load line such that the heat capacity element rests against the load line under elastic pretension. The elastically resilient material can comprise, for example, a metal spring or an elastomer.

The holding element can thus serve as a clamping means and enable a permanent connection of heat capacity element and load line by providing sufficient clamping force. As a result, the heat capacity element can assume a fixed position on the load line. Furthermore, by applying force to the heat capacity element, a firm fit can be ensured even when vibrations act from the outside.

In one embodiment, the holding element has a clamping element with a further connecting surface.

The clamping element may be connectable to the heat capacity element to retain the load line between the second connecting surface of the heat capacity element and the further connecting surface, when connected to the heat capacity element.

In one embodiment, the further connecting surface at a side facing the load line is designed to be complementary at least in regions to the insulating-sleeve-free region of the load line.

In one embodiment, the holding element comprises at least one connecting element, in particular at least one screw, in order to connect the clamping element to the heat capacity element.

In one embodiment, the heat capacity element has a solid, cuboidal body.

A large heat capacity can be achieved by such a design. Furthermore, in one embodiment, cooling ribs can be arranged on the heat capacity element, via which heat can be released to the surroundings.

In one embodiment, the heat capacity element comprises a phase-change material and/or a metal, in particular copper or aluminum.

The heat capacity element can be made of a metal material, for example copper or aluminum, in order to obtain large heat capacity and good thermal conductivity.

Alternatively, the heat capacity element may also be made of a phase-change material or may comprise a phase-change material. A phase-change material is understood herein to mean a material which, in the case of a phase change from solid to liquid, can store large amounts of heat at a constant temperature and comparatively small volumes. The phase-change material can consist, for example, of a composite made of graphite and paraffin.

By using a phase-change material, a high volume-based energy storage density can be achieved.

The invention further relates to an electrical plug connector, in particular a charging connector of a charger for charging an electric vehicle, comprising at least one contact assembly described herein.

In one embodiment, the electrical plug connector comprises two contact assemblies, wherein a housing partition made of an electrically insulating material is arranged between adjacent heat capacity elements.

Alternatively or in addition to an arrangement of an insulating material between the first connecting surface and the second connecting surface, a housing partition made of an electrically insulating material can be arranged between adjacent heat capacity elements in order to electrically insulate adjacent contact assemblies from one another.

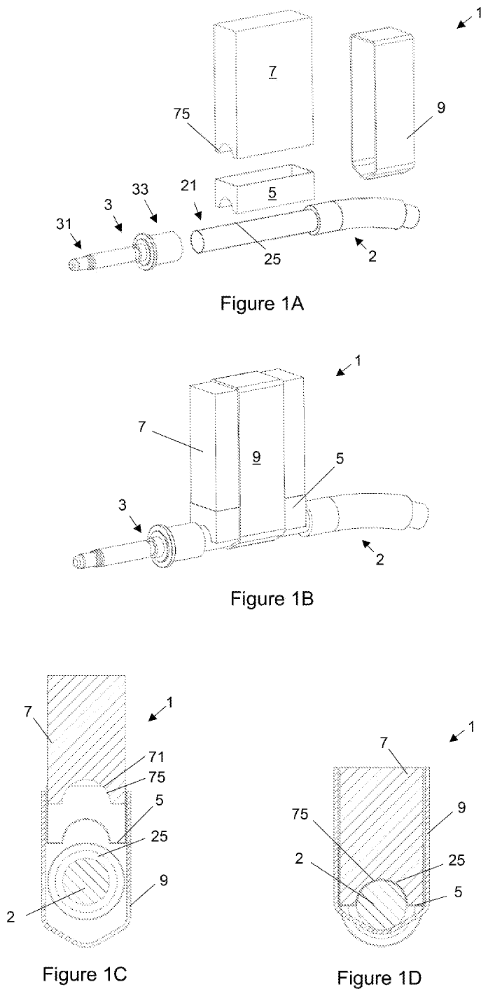

FIG. 1A shows an exploded view of a contact assembly 1, i.e., prior to arranging the heat capacity element 7 on the insulating-sleeve-free region 21 of the load line 2 according to a first embodiment. The contact element 3 shown is designed as a pin contact and has a first end region 31 for connecting to a corresponding socket of a corresponding plug connector. The second end region 33 facing away from the first end region 31 can be connected to the load line 2.

As shown, the insulating-sleeve-free region 21 of the load line 2 has a first connecting surface 25 which is designed to correspond to the shown second connecting surface 75 of the heat capacity element 7. In the embodiment shown, the first connecting surface 25 is cylindrical, or is formed by the cylindrical design of the conductor. In further embodiments, the first connecting surface can also be designed in another way, such as, for example, flat. For example, a flat connecting surface can be realized by a flat conductor. Furthermore, in embodiments, an element with the first connecting surface can be arranged on the insulating-sleeve-free region 21 (shown in FIG. 1A) of the load line 2.

In the embodiment shown, an insulating material 5 is furthermore shown which can be arranged between the heat capacity element 7 and the insulating-sleeve-free region 21 of the load line 2 for electrically insulating the heat capacity element 7 from the load line 2. In the mounted position of the contact assembly 1 shown in FIG. 1B, a first side of the insulating material 5 is in contact with the insulating-sleeve-free region 21 of the load line 2, or rests on it, and a second side of the insulating material 5, which is opposite the first side, is in contact with the connecting surface 75 of the heat capacity element 7, or rests on it. In the embodiment shown, the insulating material 5 is trough-shaped in regions, and opposite edge regions of the insulating material 5 extending in the direction of extension of the insulating material 5 are angled in the direction of the heat capacity element 7, in order thereby to achieve protection against shifting and good insulation of the edge regions of the heat capacity element 7.

In the embodiment shown in FIGS. 1A and 1B, a holding element 9 is shown, which can be arranged at least in regions around the load line 2 and the heat capacity element 7, for holding the heat capacity element 7 on the load line 2. In the embodiment shown, the holding element 9 is designed as an endless belt made of an elastically resilient material which can be slid over the heat capacity element 7 and the load line in the direction of extent of the contact element 3 or load line 2 in order to clamp the heat capacity element 7 to the load line 2, so that the heat capacity element 7 rests against the load line 2 under elastic pretension. In the embodiment shown, the geometry of the holding element 9 is already adapted to the outer surfaces of the heat capacity element 7 to be surrounded and of the load line 2.

FIGS. 1C and 1D show sectional views through the embodiment shown in FIGS. 1A and 1B. FIG. 1C shows a sectional view in the direction of extent through the exploded view of the contact assembly 1 shown in FIG. 1A. In the embodiment shown, the connecting surface 25 on the load line 2 and the connecting surface 75 on the heat capacity element 7 are each designed to correspond to one another, as cylinders. Furthermore, it is shown that the heat capacity element 7 is arranged on the load line 2 via the holding element 9.

Also, in the embodiment shown in FIG. 1C, the first connecting surface 25 and the second connecting surface 75 are cylindrical, wherein the insulating-sleeve-free region 21 of the load line 2 can be introduced at least in regions in an opening 71 of the heat capacity element 7.

FIG. 1D shows a sectional view through the contact assembly 1 shown in FIG. 1B in the mounted position.

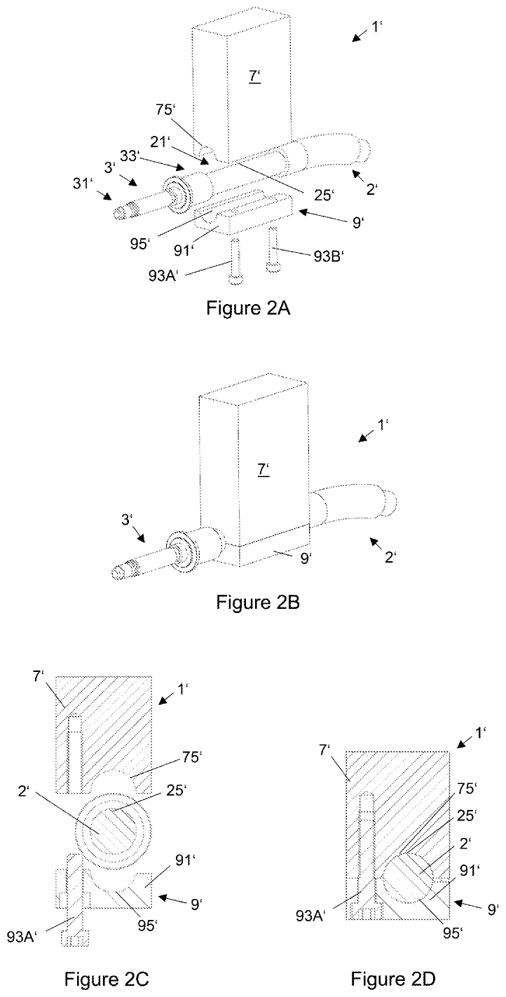

FIG. 2A shows an exploded view of a contact assembly 1′ according to a second embodiment.

The contact assembly 1′ shown differs from the contact assembly 1 previously shown in FIGS. 1A to 1D in that the holding element 9′ has a clamping element 91′ with a further connecting surface 95′. The clamping element 91′ in the embodiment shown is made of the same material as the heat capacity element 7. As shown, on a side facing the load line 2′, the further connecting surface 95′ is designed to be complementary at least in regions to the insulating-sleeve-free region 21′ of the load line 2′.

In the embodiment shown, the holding element 9′ comprises two connecting elements 93A′, 93B′ configured as screws in order to connect the clamping element 91′ to the heat capacity element 7′.

In the mounted position of the contact assembly 1′ shown in FIG. 2B, the holding element 9′ is connected to the heat capacity element 7′ and holds, or clamps, the load line 2′ between the connecting surface of the heat capacity element 7′ and the further connecting surface of the clamping element.

FIGS. 2C and 2D show sectional views through the embodiment shown in FIGS. 2A and 2B. FIG. 2C shows a sectional view in the direction of extent through the exploded view of the contact assembly 1′ shown in FIG. 2A. In the embodiment shown, the connecting surface 25′ on the load line 2′ and the connecting surface 75′ on the heat capacity element 7′ are each designed to correspond to one another, as cylinders. Furthermore, it is shown that on a side facing the load line 2′, the further connecting surface 95′ of the holding element 91′ is designed to be complementary at least in regions to the insulating-sleeve-free region 21′ of the load line 2′.

FIG. 2D shows a sectional view through the contact assembly 1′ shown in FIG. 2B in the mounted position.

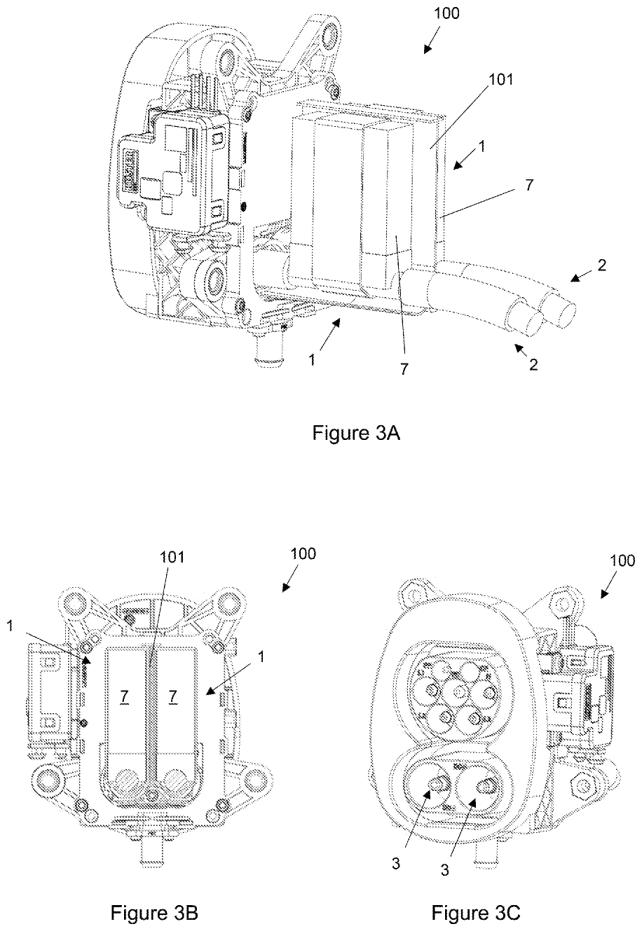

FIGS. 3A to 3C show schematic views of an electrical plug connector 100 with contact assemblies 1, 1 according to the first embodiments of the invention shown in FIGS. 1A-1D. The plug connector 100 is shown as a charging connector of a charger for charging an electric vehicle. The charging connector is shown, in particular, as a combined charging system (CCS) plug, which can also be referred to as a combo plug.

As shown, the charging connector is divided into two regions: the upper part corresponds to a so-called type 2 connection. The lower part is used for electrical charging with direct current.

In the lower part, two single-pole contact assemblies 1 according to the embodiment shown in FIGS. 1A-1D are used in the embodiment shown. Furthermore, a housing partition 101 made of an electrically insulating material is shown in FIGS. 3A and 3B, which partition is arranged between adjacent heat capacity elements 7, 7.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

1, 1′ Contact assembly
2, 2′ Load line
21, 21′ Insulating-sleeve-free region
3, 3′ Contact element
31, 31′ First end region
33, 33′ Second end region
25, 25′, 75, 95′ Connecting surface
5 Insulating material
7, 7′ Heat capacity element
71 Opening
9, 9′ Holding element
91′ Clamping element
93A′, 93B′ Connecting element
100 Electrical plug connector
101 Housing partition

1. A contact assembly for an electrical plug connector, comprising:
at least one contact element with a first end region configured to connect to a corresponding plug connector, and a second end region facing away from the first end region;
a load line, an end section of an insulating-sleeve-free region of the load line being connectable to the second end region of the at least one contact element; and
a heat capacity element arrangeable at least in regions on the insulating-sleeve-free region of the load line.

2. The contact assembly of claim 1, wherein the insulating-sleeve-free region of the load line has a first connecting surface, and the heat capacity element has a second connecting surface corresponding to the first connecting surface.

3. The contact assembly of claim 2, wherein the first connecting surface and the second connecting surface are flat or curved.

4. The contact assembly of claim 2, wherein the first connecting surface and the second connecting surface are cylindrical, and
wherein the insulating-sleeve-free region of the load line lies at least in regions in an opening of the heat capacity element.

5. The contact assembly of claim 1, further comprising:
an insulating material arrangeable between the first connecting surface and the second connecting surface for electrically insulating the heat capacity element from the load line.

6. The contact assembly of claim 1, further comprising:
a holding element configured to hold the heat capacity element on the load line.

7. The contact assembly of claim 6, wherein, in a mounted position, the holding element extends as a belt around the load line and the heat capacity element.

8. The contact assembly of claim 6, wherein the holding element comprises an elastically resilient material.

9. The contact assembly of claim 6, wherein the holding element has a clamping element with a further connecting surface.

10. The contact assembly of claim 9, wherein, on a side facing the load line, the further connecting surface is complementary at least in regions to the insulating-sleeve-free region of the load line.

11. The contact assembly of claim 9, wherein the holding element comprises at least one connecting element comprising at least one screw in order to connect the clamping element to the heat capacity element.

12. The contact assembly of claim 1, wherein the heat capacity element has a solid, cuboidal body.

13. The contact assembly of claim 1, wherein the heat capacity element comprises a phase-change material or a metal comprising copper or aluminum.

14. An electrical plug connector, comprising:
at least one contact assembly of claim 1.

15. The electrical plug connector of claim 14, wherein the at least one contact assembly comprises two contact assemblies, and
wherein a housing partition comprising an electrically insulating material is arranged between adjacent heat capacity elements.

16. The electrical plug connector of claim 14, wherein the electrical plug connector comprises a charging connector of a charger for charging an electric vehicle.
